(19) United States
(12) Patent Application Publication
(10) Pub. No.: US 2025/0116700 A1
(43) Pub. Date: Apr. 10, 2025

(54) POWER MODULE AND POWER CONVERTER INCLUDING SAME

(71) Applicant: MITSUBISHI HEAVY INDUSTRIES, LTD., Tokyo (JP)

(72) Inventors: Norihito Yanagita, Tokyo (JP); Takashi Masuzawa, Tokyo (JP); Masahiko Ezumi, Tokyo (JP)

(73) Assignee: MITSUBISHI HEAVY INDUSTRIES, LTD., Tokyo (JP)

(21) Appl. No.: 18/865,751

(22) PCT Filed: Feb. 7, 2023
(86) PCT No.: PCT/JP2023/004011

§ 371 Date: Nov. 14, 2024

(30) Foreign Application Priority Data
May 20, 2022 (JP) 2022-082771

(51) Int. Cl. G01R 31/311; G01R 31/28; H01L 23/538; H01L 25/16; H10F 39/95

(52) U.S. Cl. CPC G01R 31/311; G01R 31/2884; H01L 23/5385; H01L 25/167; H10F 39/95

(57) ABSTRACT

A power module according to the present disclosure comprises: a circuit board disposed on a main surface of a base plate; a main terminal part capable of inputting power to a circuit pattern of the circuit board; an output terminal part capable of outputting the power converted by a power semiconductor element connected to the circuit pattern; a case having a side wall part that while being disposed on the main surface, surrounds the circuit board in a main surface-widening direction to define a housing space for housing the circuit board, and a lid part that is disposed on the side wall part to close off the housing space, thereby blocking off the inside of the housing space; an insulating part disposed inside the housing space to bury the circuit board; and an optical detection part disposed in the case and capable of detecting the light generated inside the housing space due to the entrance of the light from a distal end surface. A plurality of distal end surfaces of the optical detection part are arranged side by side along a side edge part of the circuit pattern opposed to an inner surface of the side wall part in the housing space so that an optical detection range includes the side edge part.

### TECHNICAL FIELD

The present disclosure relates to a power module and a power conversion device including the same.

This application claims priority to Japanese Patent Application No. 2022-82771, filed in Japan on May 20, 2022, the contents of which are incorporated herein by reference.

### BACKGROUND ART

For example, PTL 1 discloses a power semiconductor module including a power semiconductor element, an insulating substrate, and an optical fiber in which a Fiber Bragg Grating (FBG) is formed. The FBG formed in the optical fiber is disposed in a vicinity of the power semiconductor element. When partial discharge occurs in the vicinity of the power semiconductor element, the FBG expands and contracts due to a sound pressure of an acoustic emission (AE) wave caused by the partial discharge. The partial discharge is detected by utilizing a phenomenon in which an optical signal wavelength changes with the expansion and contraction of the FBG.

### CITATION LIST

### Patent Literature

[PTL 1] International Publication No. WO2017/159211

### SUMMARY OF INVENTION

### Technical Problem

A partial discharge source in the power semiconductor module is not limited to the vicinity of the semiconductor element, and an end portion of a circuit pattern may be a starting point. For this reason, in the technique described in PTL 1, there is a case where the partial discharge occurring from the end portion of the circuit pattern cannot be accurately detected.

An object of the present disclosure is to provide a power module capable of accurately detecting the partial discharge occurring from an end portion of a circuit pattern, and a power conversion device including the same.

### Solution to Problem

In order to solve the above problem, a power module according to the present disclosure includes a base plate; a circuit board that is disposed on a main surface of the base plate; a main terminal portion configured to input power to a circuit pattern of the circuit board; an output terminal portion configured to output the power converted by a power semiconductor element connected to the circuit pattern; a case that includes a side wall portion that surrounds the circuit board from a direction in which the main surface extends in a state in which the side wall portion is disposed on the main surface to define a housing space for housing the circuit board, and a lid portion that is disposed on the side wall portion so as to close the housing space to close an inside of the housing space; an insulating portion that is disposed in the housing space so as to embed the circuit board from a direction perpendicular to the main surface; and a light detection unit that is disposed in the case and configured to detect light generated in the housing space when light is incident from a tip surface of the light detection unit, in which a plurality of the tip surfaces of the light detection unit are arranged side by side along a side edge portion of the circuit pattern that faces an inner surface of the side wall portion in the housing space so that a light detection range includes the side edge portion.

A power conversion device according to the present disclosure includes the power module; a gate drive device configured to control switching of the power semiconductor element; a photoelectric conversion element configured to convert light from the light detection unit into a light reception signal voltage; a synchronization processing device configured to synchronize a timing at which a voltage applied from the gate drive device to the power semiconductor element changes with a timing at which the photoelectric conversion element converts the light into the light reception signal voltage and acquiring the light reception signal voltage from the photoelectric conversion element; and a detection device configured to detect presence or absence of an abnormality in the circuit pattern within the light detection range based on a magnitude of the light reception signal voltage acquired by the synchronization processing device.

### Advantageous Effects of Invention

According to the present disclosure, it is possible to provide a power module capable of accurately detecting partial discharge occurring from an end portion of a circuit pattern, and a power conversion device including the same.

### BRIEF DESCRIPTION OF DRAWINGS

FIG. 1 is a perspective view illustrating a schematic configuration of a power conversion device according to an embodiment of the present disclosure.

FIG. 2 is a plan view of a power module according to a first embodiment of the present disclosure.

FIG. 3 is a cross-sectional view taken along line III-III illustrated in FIG. 2.

FIG. 4 is a diagram illustrating a relationship among a power module, a gate drive device, a photoelectric conversion element, a synchronization processing device, and a detection device.

FIG. 5 is a graph illustrating a relationship among a voltage applied to a power semiconductor element, an input signal input to the synchronization processing device, and a light reception signal voltage acquired by the detection device.

FIG. 6 is a plan view of a power module according to a second embodiment of the present disclosure.

FIG. 7 is a cross-sectional view taken along line VII-VII illustrated in FIG. 6.

FIG. 8 is a cross-sectional view of a power module according to a third embodiment of the present disclosure, and is a view corresponding to a portion illustrated in FIG. 7.

FIG. 9 is a cross-sectional view of a power module according to another embodiment of the present disclosure, and is a view corresponding to the portion illustrated in FIG. 7.

### DESCRIPTION OF EMBODIMENTS

Hereinafter, an embodiment of a power conversion device according to the present disclosure will be described with reference to the accompanying drawings.

### First Embodiment

The power conversion device is a device that converts DC power into three-phase AC power or the like. Examples of the power conversion device of the present embodiment include an inverter used in a system of a power plant or the like, and an inverter used for driving an electric motor of an electric vehicle or the like.

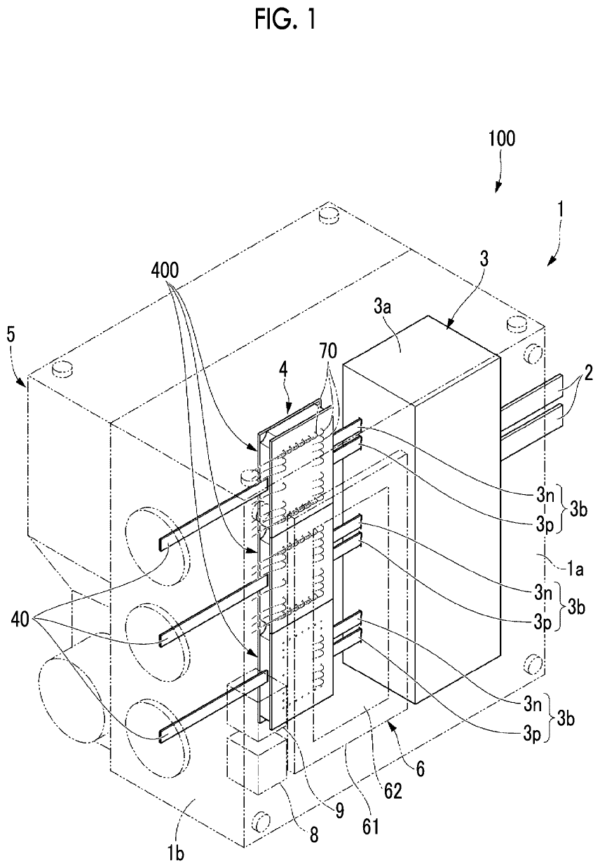

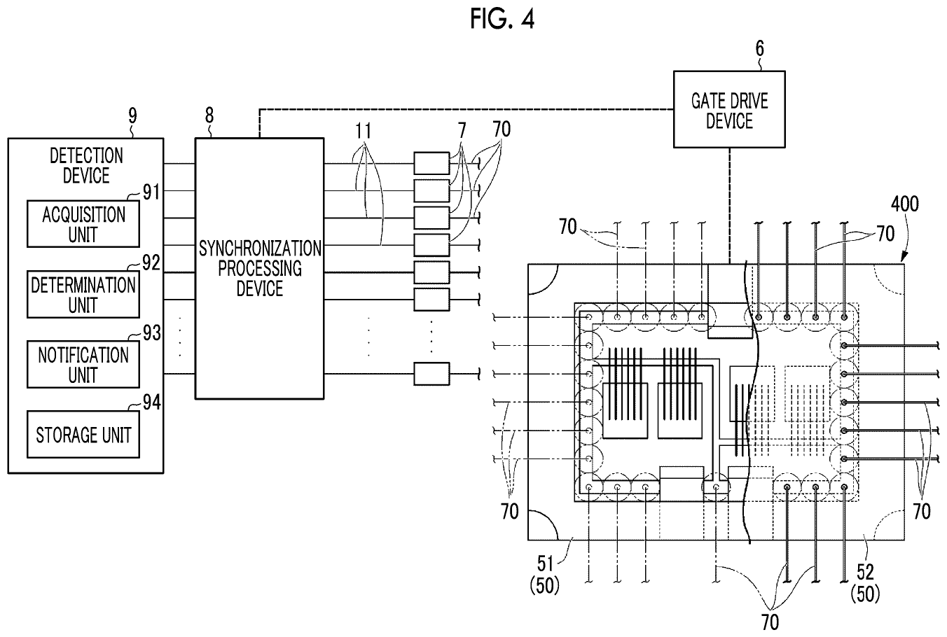

As illustrated in FIG. 1, a power conversion device 100 includes a casing 1, an external input conductor 2, a capacitor 3, a power conversion unit 4, a cooling device 5, a gate drive device 6, a photoelectric conversion element 7, a synchronization processing device 8, a detection device 9, and a cable 11. In FIG. 1, the photoelectric conversion element 7 and the cable 11 are not illustrated due to space limitations, but are illustrated in FIG. 4.

### Casing

The casing 1 forms a part of an outer shell of the power conversion device 100. The casing 1 in the present embodiment is formed of a metal such as aluminum, a synthetic resin, or the like, and has a rectangular parallelepiped shape. The casing 1 has two side surfaces which are disposed opposite one another. Hereinafter, of these two side surfaces, the side surface facing one side is referred to as an “input side surface 1a”, and the side surface facing the other side is referred to as an “output side surface 1b”. The external input conductor 2 for inputting DC power is led out from the input side surface 1a.

### External Input Conductor

The external input conductors 2 are a pair of electrical conductors (bus bars) that supply DC power supplied from a power system or the like outside the power conversion device 100 to the capacitor 3. The external input conductor 2 in the present embodiment is formed of, for example, a metal containing copper or the like. One end of the external input conductor 2 is connected to the capacitor 3 housed in the casing 1, and the other end of the external input conductor 2 extends to the outside of the casing 1 in a direction intersecting the input side surface 1a of the casing 1.

### Capacitor

The capacitor 3 is a smoothing capacitor for storing charge input from the external input conductor 2 and suppressing voltage fluctuation associated with power conversion. The DC voltage whose ripple is suppressed and smoothed by passing through the capacitor 3 is supplied to the power conversion unit 4. The capacitor 3 includes a capacitor body 3a and a connection conductor 3b. The capacitor body 3a is a portion that mainly exhibits the function of the smoothing capacitor described above.

The connection conductor 3b is an electrical conductor (bus bar) for transmitting power from the capacitor body 3a to the power conversion unit 4. The connection conductor 3b is formed of, for example, a metal containing copper or the like. The connection conductor 3b has a positive electrode side terminal 3p and a negative electrode side terminal 3n.

The positive electrode side terminal 3p forms a positive electrode of the capacitor 3, and is a current path that connects the capacitor body 3a and a positive electrode of a power module 400 in the power conversion unit 4. The negative electrode side terminal 3n forms a negative electrode of the capacitor 3, and is a current path that connects the capacitor body 3a and a negative electrode of the power module 400 in the power conversion unit 4.

The positive electrode side terminal 3p and the negative electrode side terminal 3n are arranged side by side at an interval. One end of each of the positive electrode side terminal 3p and the negative electrode side terminal 3n is connected to the capacitor body 3a. A detailed illustration of a connection state between the positive electrode side terminal 3p and the negative electrode side terminal 3n and the capacitor body 3a is omitted. The other end of each of the positive electrode side terminal 3p and the negative electrode side terminal 3n is connected to the power module 400.

### Power Conversion Unit

The power conversion unit 4 converts the voltage input from the capacitor 3. In order to output three-phase AC power, the power conversion unit 4 in the present embodiment includes three power modules 400 respectively responsible for outputs for U phase, V phase, and W phase. Therefore, the power conversion device 100 in the present embodiment is a three-phase inverter including three power modules 400. The power conversion unit 4 is accommodated in the casing 1.

### Power Module

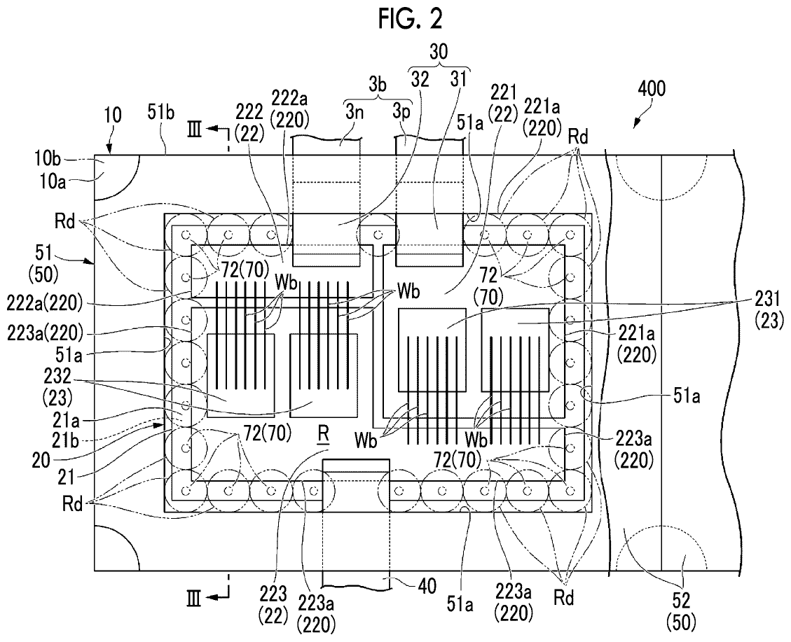

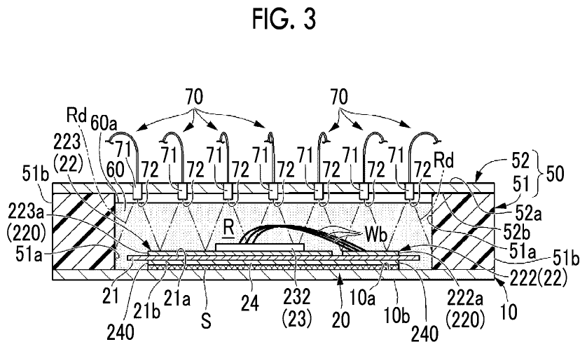

The power module 400 is a device that converts input power and outputs the converted power. As illustrated in FIGS. 2 and 3, the power module 400 includes a base plate 10, a circuit board 20, a main terminal portion 30, an output terminal portion 40, a case 50, an insulating portion 60, a light detection unit 70, and a bonding wire Wb. In FIG. 2, illustration of the insulating portion 60 is omitted due to space limitations.

### Base Plate

The base plate 10 is a member having a flat plate shape. The base plate 10 has a main surface 10a and a back surface 10b located on a back side of the main surface 10a. That is, the main surface 10a and the back surface 10b of the base plate 10 are back-to-back in a state of being parallel to each other. The back surface 10b of the base plate 10 is fixed to the cooling device 5 (see FIG. 1) via a bonding material (not illustrated) such as grease, a heat dissipation sheet, or solder. For example, a metal including copper or the like is adopted for the base plate 10 in the present embodiment. The metal such as aluminum is adopted for the base plate 10.

### Circuit Board

The circuit board 20 includes a first insulating plate 21, a front surface pattern 22 (circuit pattern), a power semiconductor element 23, and a back surface pattern 24 (circuit pattern).

The first insulating plate 21 has a flat plate shape. The first insulating plate 21 has a first surface 21a and a second surface 21b located on the back side of the first surface 21a. That is, the first surface 21a and the second surface 21b of the first insulating plate 21 are back-to-back in a state of being parallel to each other. On the second surface 21b of the first insulating plate 21, a back surface pattern 24 which is a pattern of copper foil or the like is formed on one surface. The back surface pattern 24 is fixed to the center of the main surface 10a of the base plate 10 via a bonding material S. The back surface pattern 24 is formed to have a predetermined thickness in a direction perpendicular to the second surface 21b.

The first insulating plate 21 in the present embodiment is formed of, for example, an insulating material such as ceramic. As the insulating material forming the first insulating plate 21, paper phenol, paper epoxy, glass composite, glass epoxy, glass polyimide, fluororesin, or the like can be adopted in addition to ceramic.

The front surface pattern 22 is a pattern of copper foil or the like formed on the first surface 21a of the first insulating plate 21 and extending in a planar shape. The front surface pattern 22 is formed by, for example, being fixed to the first surface 21a of the first insulating plate 21 by adhesion or the like and then being subjected to etching or the like. The front surface pattern 22 is formed to have a predetermined thickness in a direction perpendicular to the first surface 21a.

A plurality of the front surface patterns 22 are disposed on the first surface 21a of the first insulating plate 21. The plurality of front surface patterns 22 are disposed adjacent to each other with a gap therebetween in a direction in which the first insulating plate 21 extends. In the present embodiment, a case where three front surface patterns 22 are disposed on the first surface 21a will be described as an example. Hereinafter, as shown in FIG. 2, for convenience of description, these three front surface patterns 22 are referred to as a first front surface pattern 221, a second front surface pattern 222, and a third front surface pattern 223.

The first front surface pattern 221 is a pattern to which a DC voltage from the positive electrode side terminal 3p of the capacitor 3 is applied. The second front surface pattern 222 is a pattern for returning the DC voltage to the negative electrode side terminal 3n of the capacitor 3. That is, the first front surface pattern 221 corresponds to an inlet portion of a loop between a P-type and an N-type formed in the front surface pattern 22, and the second front surface pattern 222 corresponds to an outlet portion of the loop between the P-type and the N-type. The third front surface pattern 223 is a pattern for outputting an AC current to the outside of the power module 400.

The power semiconductor element 23 is a circuit element that converts power by means of a switching operation of turning on and off a voltage or a current. The power semiconductor element 23 is, for example, a switching element such as a MOSFET or an IGBT. In the present embodiment, as an example, four power semiconductor elements 23 are connected to the front surface pattern 22 of the circuit board 20.

The four power semiconductor elements 23 in the present embodiment include two first power semiconductor elements 231 and two second power semiconductor elements 232. The first power semiconductor element 231 is connected to the first front surface pattern 221. The second power semiconductor element 232 is connected to the third front surface pattern 223.

When the power semiconductor element 23 is a MOSFET, the power semiconductor element 23 includes an input terminal (not illustrated) corresponding to a drain, an output terminal (not illustrated) corresponding to a source, and a control signal terminal (not illustrated) corresponding to a gate. A signal for controlling switching of the power semiconductor element 23 is input to the control signal terminal from the outside of the power module 400.

An input terminal of the power semiconductor element 23 is electrically connected to the front surface pattern 22 via the bonding material S. One end of a bonding wire Wb as a conducting wire is electrically connected to an output terminal of the power semiconductor element 23. The other end of the bonding wire Wb is connected to a front surface pattern 22 different from the front surface pattern 22 to which the input terminal of the power semiconductor element 23 whose one end is connected is connected. The bonding wire Wb is formed of, for example, a metal such as aluminum. That is, the front surface patterns 22 formed on the first surface 21a are electrically connected to each other by wire bonding.

An input terminal of the first power semiconductor element 231 is connected to the first front surface pattern 221. One end of the bonding wire Wb, connected to the output terminal of the first power semiconductor element 231, is connected to the third front surface pattern 223 at the other end. An input terminal of the second power semiconductor element 232 is connected to the third front surface pattern 223. One end of the bonding wire Wb, connected to the output terminal of the second power semiconductor element 232, is connected to the second front surface pattern 222 at the other end.

DC power is input to the input terminal of the first power semiconductor element 231 through the first front surface pattern 221, and the input DC power is converted into AC power by the first power semiconductor element 231. The converted AC power is output from the output terminal of the first power semiconductor element 231 to the third front surface pattern 223 through the bonding wire Wb.

AC power is input to the input terminal of the second power semiconductor element 232 through the third front surface pattern 223, and the input AC power is converted into DC power by the second power semiconductor element 232. The converted DC power is output from an output terminal (not illustrated) in the second power semiconductor element 232 to the second front surface pattern 222 through the bonding wire Wb.

A control signal generated by the gate drive device 6 provided outside the power module 400 is input to each power semiconductor element 23. The power semiconductor element 23 performs switching in accordance with the control signal from the gate drive device 6. When the power semiconductor element 23 is an IGBT, the power semiconductor element 23 includes an input terminal corresponding to a collector, an output terminal corresponding to an emitter, and a control signal terminal corresponding to a gate.

### Main Terminal Portion

The main terminal portion 30 is an electrical conductor (bus bar) that exchanges DC power between the capacitor 3 and the circuit board 20. The main terminal portion 30 is formed of, for example, a metal including copper or the like. The main terminal portion 30 includes a P-type terminal 31 as a positive electrode and an N-type terminal 32 as a negative electrode. The P-type terminal 31 and the N-type terminal 32 are arranged side by side with a gap therebetween. The P-type terminal 31 has one end connected to the first front surface pattern 221 and the other end connected to the positive electrode side terminal 3p of the capacitor 3. The N-type terminal 32 has one end connected to the second front surface pattern 222 and the other end connected to the negative electrode side terminal 3n of the capacitor 3.

### Output Terminal Portion

The output terminal portion 40 is an electrical conductor (bus bar) capable of outputting AC power converted by the power semiconductor element 23 connected to the front surface pattern 22 to a load (not illustrated) provided outside the power conversion device 100. The output terminal portion 40 is formed of, for example, a metal including copper or the like.

The output terminal portion 40 has one end connected to the third front surface pattern 223 of the circuit board 20, and the other end that extends in a direction intersecting the output side surface 1b of the casing 1 (see FIG. 1). The output terminal portion 40 in the present embodiment has the other end that extends outward beyond the output side surface 1b of the casing 1. For example, a wire (not illustrated) for power output connected to a load such as a motor is connected to the other end of the output terminal portion 40.

### Case

The case 50 is a member that mechanically reinforces the main terminal portion 30 and the output terminal portion 40 in a state of being fixed to the main surface 10a of the base plate 10. The case 50 is made of, for example, a synthetic resin material (insulating material). For example, polyphenylene sulfide (PPS) can be adopted as the material forming the case 50 in the present embodiment. A synthetic resin material other than PPS may be adopted for the case 50. The case 50 is fixed to the main surface 10a of the base plate 10 by, for example, an adhesive agent.

The case 50 in the present embodiment has a side wall portion 51 and a lid portion 52. In FIG. 2, a part of the lid portion 52 of the case 50 included in the power module 400 illustrated in a central portion in FIG. 2 is omitted for convenience of illustration.

In a state where the side wall portion 51 is disposed on the main surface 10a of the base plate 10, the side wall portion 51 covers the P-type terminal 31 and the N-type terminal 32 of the main terminal portion 30 and the output terminal portion 40 from the outside, and surrounds the circuit board 20 from a direction in which the main surface 10a extends. In other words, the side wall portion 51 surrounds the circuit board 20 in a direction along the main surface 10a of the base plate 10. Therefore, the side wall portion 51 has an inner surface 51a that defines a space in which the circuit board 20 is housed together with the base plate 10. The side wall portion 51 has an outer surface 51b facing the opposite side to the inner surface 51a. In the present embodiment, this space in which the circuit board 20 is housed is referred to as a “housing space R”.

Here, the front surface pattern 22 of the circuit board 20 has side edge portions 220 (a first side edge portion 221a, a second side edge portion 222a, and a third side edge portion 223a) facing the inner surface 51a of the side wall portion 51 in the housing space R. The side edge portion 220 is a surface corresponding to a thickness portion of the front surface pattern 22. That is, the side edge portion 220 is an end portion of the front surface pattern 22. The first front surface pattern 221 has a first side edge portion 221a facing the inner surface 51a of the side wall portion 51. The second front surface pattern 222 has a second side edge portion 222a facing the inner surface 51a of the side wall portion 51. The third front surface pattern 223 has a third side edge portion 223a facing the inner surface 51a of the side wall portion 51. The back surface pattern 24 of the circuit board 20 has a side edge portion 240 facing the inner surface 51a of the side wall portion 51 in the housing space R. The side edge portion 240 is a surface corresponding to the thickness portion of the back surface pattern 24. That is, the side edge portion 240 is an end portion of the back surface pattern 24.

As illustrated in FIG. 3, the lid portion 52 has a flat plate shape. The lid portion 52 is integrally disposed with the side wall portion 51 so as to close the housing space R. The lid portion 52 is disposed on the side wall portion 51 to close the housing space R. In the present embodiment, since the lid portion 52 is disposed on the side wall portion 51, the inside of the housing space R becomes a darkroom. The lid portion 52 in the present embodiment is fixed to the side wall portion 51 from a direction perpendicular to the main surface 10a via an adhesive agent or the like. The lid portion 52 has a contact surface 52b that comes into contact with the side wall portion 51 and a surface 52a that faces the opposite side to the contact surface 52b.

### Insulating Portion

The insulating portion 60 is an insulating sealing material disposed in the housing space R. The insulating portion 60 is formed of a transparent filler such as silicone gel. The insulating portion 60 is disposed in the housing space R so as to embed the circuit board 20 from the direction perpendicular to the main surface 10a of the base plate 10. Specifically, the insulating portion 60 in the housing space R is disposed so as to cover the surfaces of the circuit board 20 and the bonding wires Wb. The circuit board 20 exposed in the housing space R is sealed by filling the housing space R with a liquid potting material (transparent filler) in a manufacturing process of the power module 400.

The potting material filled in the housing space R is cured at a predetermined temperature for a predetermined time to cure the insulating portion 60 thermally. The insulating portion 60 electrically insulates the circuit board 20 in the housing space R from a space outside the power module 400. As the potting material in the present embodiment, for example, silicone gel or the like can be used. A filling material other than silicone gel may be adopted as the potting material as long as it can be optically transmitted and detected. The insulating portion 60 has an upper surface 60a which is a liquid surface generated when the potting material is filled. The upper surface 60a faces the contact surface 52b of the lid portion 52 via a gap.

### Light Detection Unit

The light detection unit 70 is an optical fiber cable capable of detecting light generated in the housing space R. A plurality of the light detection units 70 are disposed on the lid portion 52 of the case 50. The light detection unit 70 has a tip portion 71. The tip portion 71 is fixed to the lid portion 52 in a state of penetrating from the surface 52a of the lid portion 52 of the case 50 to the contact surface 52b.

A tip surface 72 of the tip portion 71 is disposed in the housing space R. Specifically, the tip surface 72 is disposed in a gap between the upper surface 60a of the insulating portion 60 and the contact surface 52b of the lid portion 52. That is, the tip portion 71 protrudes from the contact surface 52b of the lid portion 52 toward the base plate 10. The tip surface 72 faces the main surface 10a in a state of being parallel to the main surface 10a. The light detection unit 70 can detect the light generated in the housing space R when the light is incident from the tip surface 72.

Each light detection unit 70 has a light detection range Rd that is a range in which light can be detected. The light detection range Rd in the present embodiment has a conical shape extending at an angle of, for example, 10° to 30° from the tip surface 72 of the tip portion 71, serving as a starting point. As illustrated in FIG. 2, the tip surfaces 72 of the plurality of light detection units 70 are arranged side by side along the side edge portion 220 such that the light detection range Rd extending from the tip surface 72 includes the side edge portion 220 of the front surface pattern 22 facing the inner surface 51a of the side wall portion 51 in the housing space R. Among the plurality of light detection units 70 arranged side by side along the side edge portion 220, two adjacent light detection units 70 are disposed such that at least parts of the light detection ranges Rd extending from the respective tip surfaces 72 overlap each other when viewed from the direction perpendicular to the main surface 10a.

At this time, the tip surface 72 of the light detection unit 70 is not disposed between the lid portion 52 of the case 50 and the P-type terminal 31 connected to the first front surface pattern 221, the N-type terminal 32 connected to the second front surface pattern 222, and the output terminal portion 40 connected to the third front surface pattern 223. Therefore, when viewed from the direction perpendicular to the main surface 10a, the light detection ranges Rd of the two adjacent light detection units 70, which have the P-type terminal 31, the N-type terminal 32, and the output terminal portion 40 interposed therebetween, do not overlap each other.

### Cooling Device

As shown in FIG. 1, the cooling device 5 is a device that mainly cools the power module 400 of the power conversion unit 4. The cooling device 5 is provided so as to be stacked on the casing 1, and is integrated by being fixed to the casing 1. Therefore, the cooling device 5 forms a part of an outer shell of the power conversion device 100 together with the casing 1. For example, a liquid refrigerant such as water is introduced into the cooling device 5 from the outside. The liquid refrigerant exchanges heat with the power module 400 and is heated, thereby cooling the power module 400.

### Gate Drive Device

The gate drive device 6 is a circuit board capable of controlling switching of the power semiconductor element 23. The gate drive device 6 is housed in the casing 1. As illustrated in FIG. 1, the gate drive device 6 in the present embodiment includes a second insulating plate 61, a gate drive pattern 62, and a gate driver IC (not illustrated).

### Second Insulating Plate

The second insulating plate 61 has a flat plate shape. The second insulating plate 61 is disposed in the casing 1 in a state of being spaced apart from the power module 400 of the power conversion unit 4. Specifically, the second insulating plate 61 is fixed to the inner surface of the casing 1, for example.

### Gate Drive Pattern

The gate drive pattern 62 is a circuit pattern for controlling switching of the power semiconductor element 23. The gate drive pattern 62 is a pattern of copper foil or the like formed on the second insulating plate 61. The gate driver IC capable of generating a control signal to be input to the control signal terminal of the power semiconductor element 23 is connected to the gate drive pattern 62 in the present embodiment. The gate driver IC generates a gate voltage for driving the gate of the power semiconductor element 23. The gate drive pattern and the power semiconductor element 23 are connected by a connection electrical conductor (not illustrated). The gate drive pattern 62 inputs (applies) the gate voltage generated by the gate driver IC to the power semiconductor element 23 through the electrical conductor.

### Photoelectric Conversion Element

The photoelectric conversion element 7 is an element capable of converting light from the light detection unit 70 into a light reception signal voltage. As the photoelectric conversion element 7 in the present embodiment, for example, a photodiode or the like can be adopted. The photoelectric conversion element 7 is housed in the casing 1 (not illustrated in FIG. 1). As shown in FIG. 4, the photoelectric conversion elements 7 are connected one by one to the end portions of the respective light detection units 70 on the side opposite to the tip surface 72 side. Therefore, the light incident on the light detection unit 70 from the tip surface 72 is guided to the photoelectric conversion element 7.

The light guided to the photoelectric conversion element 7 through the light detection unit 70 is photoelectrically converted into an electric signal by the photoelectric conversion element 7. In the present embodiment, the voltage of the electric signal generated by the photoelectric conversion of the photoelectric conversion element 7 is referred to as a “light reception signal voltage”. The photoelectric conversion element 7 acquires a light reception signal voltage from the light from the light detection unit 70.

### Synchronization Processing Device

The synchronization processing device 8 is electrically connected to each photoelectric conversion element 7 via a cable 11. The synchronization processing device 8 is electrically connected to the gate drive pattern 62 of the gate drive device 6. As illustrated in FIG. 1, the synchronization processing device 8 in the present embodiment is housed in, for example, the casing 1.

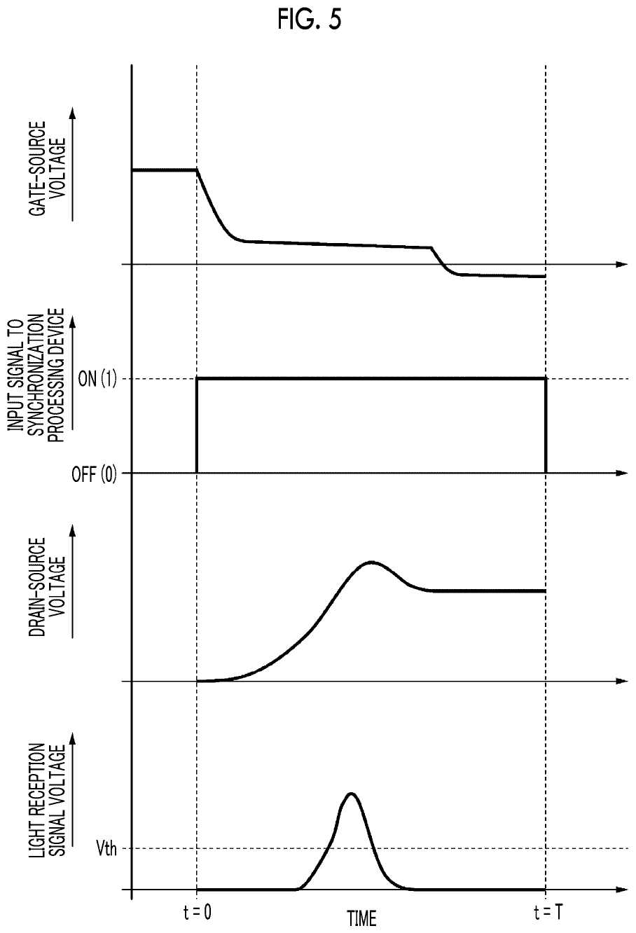

Here, an example of the operation of the synchronization processing device 8 will be described with reference to FIG. 5. When a voltage is applied from the gate drive pattern 62 of the gate drive device 6 to the power semiconductor element 23 in the power module 400, a gate-source voltage that is a potential difference between a control signal terminal (gate) and an output terminal (source) of the power semiconductor element 23 changes (the uppermost graph in FIG. 5). At this time, the gate drive pattern 62 transmits a signal indicating that a voltage is applied to the power semiconductor element 23 to the synchronization processing device 8 (a signal indicating “ON (1)” in the second graph from the top in FIG. 5). Further, as the gate-source voltage changes, a drain-source voltage, which is a potential difference between the output terminal (source) and the input terminal (drain) of the power semiconductor element 23, changes (the second graph from the bottom in FIG. 5).

The synchronization processing device 8 receives a signal indicating that a voltage has been applied to the power semiconductor element 23 from the gate drive pattern 62, and simultaneously receives an electric signal from the photoelectric conversion element 7. That is, the synchronization processing device 8 synchronizes the timing at which the voltage applied from the gate drive device 6 to the power semiconductor element 23 changes with the timing at which the photoelectric conversion element 7 converts light into a light reception signal voltage. The synchronization processing device 8 synchronizes these timings and acquires the light reception signal voltage over time from the synchronized time (t=0) until a predetermined time T elapses (t=T). The synchronization processing device 8 transmits a signal indicating the light reception signal voltage acquired during the predetermined time T to the detection device 9. The light reception signal voltage in the present specification includes a plurality of voltage values rather than a voltage value of a certain pinpoint. An example of the light reception signal voltage is illustrated in FIG. 5 (the lowermost graph in FIG. 5). In the graph of the light reception signal voltage in FIG. 5, the light reception signal voltage acquired by the synchronization processing device when the partial discharge occurs is illustrated as an example.

### Detection Device

The detection device 9 detects presence or absence of an abnormality in the circuit pattern within the light detection range Rd in which the light detection unit 70 can detect light based on the magnitude of the light reception signal voltage acquired by the synchronization processing device 8. As illustrated in FIG. 1, the detection device 9 in the present embodiment is housed in the casing 1. As illustrated in FIG. 4, the detection device 9 according to the present embodiment includes an acquisition unit 91, a determination unit 92, a notification unit 93, and a storage unit 94.

The acquisition unit 91 acquires the light reception signal voltage by receiving a signal indicating the light reception signal voltage transmitted from the synchronization processing device 8. The acquisition unit 91 sends the acquired light reception signal voltage to the determination unit 92.

When receiving the light reception signal voltage from the acquisition unit 91, the determination unit 92 compares a voltage value included in the light reception signal voltage with a predetermined threshold voltage Vth. When at least one of the voltage values included in the light reception signal voltage is equal to or higher than the threshold voltage Vth, the determination unit 92 determines that “there is an abnormality”. On the other hand, when all the voltage values included in the light reception signal voltage are less than the threshold voltage Vth, the determination unit 92 determines that “there is no abnormality”. The threshold voltage Vth is stored in advance in the storage unit 94, for example.

The notification unit 93 notifies a user of the power conversion device 100 when it is determined by the determination unit 92 that “there is an abnormality”. Specifically, for example, the notification unit 93 transmits a signal indicating the start of lighting to a state display lamp or the like provided in the power conversion device 100. The notification unit 93 ends the process when it is determined by the determination unit 92 that “there is no abnormality”

### Operations and Effects

The power input from the capacitor 3 to the front surface pattern 22 through the P-type terminal 31 of the main terminal portion 30 is converted by switching of the power semiconductor element 23, and is then used for rotation of a motor or the like (load) provided outside the power conversion device 100 through the output terminal portion 40. The power used for the rotation of the motor or the like flows into the front surface pattern 22 again through the output terminal portion 40, is converted by switching of the power semiconductor element 23, and then returns to the capacitor 3 through the N-type terminal 32 of the main terminal portion 30. In the loop between the P-type and the N-type, when a large current from the capacitor 3 is converted by switching of the power semiconductor element 23, a rapid voltage fluctuation occurs. This voltage fluctuation may cause partial discharge starting from the side edge portion 220 of the front surface pattern 22.

According to the above configuration, since the plurality of light detection units 70 are arranged side by side along the side edge portion 220 so that the light detection range Rd of the light detection unit 70 includes the side edge portion 220 of the circuit pattern, the light of the partial discharge generated from the side edge portion 220 of the front surface pattern 22 is incident on the light detection unit 70 from the tip surface 72. That is, the light of the partial discharge from the side edge portion 220 is detected by the light detection unit 70. Therefore, the partial discharge occurring from the end portion of the front surface pattern 22, that is, the side edge portion 220, can be accurately detected.

In addition, two adjacent light detection units 70 among the plurality of light detection units 70 arranged side by side along the side edge portion 220 are disposed such that at least parts of the respective light detection ranges Rd overlap each other when viewed from the direction perpendicular to the main surface 10a. Therefore, the partial discharge occurring from the front surface pattern 22 can be detected with high accuracy.

In addition, since the housing space R defined by the side wall portion 51 is closed by the lid portion 52, the inside of the housing space R becomes a darkroom, and thus it is possible to suppress detection of light other than partial discharge by means of the light detection unit 70. That is, it is possible to suppress detection of light that becomes noise by means of the light detection unit 70. As a result, the occurrence of erroneous detection can be suppressed.

In addition, the synchronization processing device 8 synchronizes the timing at which the voltage applied from the gate drive device 6 to the power semiconductor element 23 starts to change and the timing at which the photoelectric conversion element 7 starts to convert light into a light reception signal voltage. Therefore, the detection device 9 starts detecting the presence or absence of the partial discharge from the timing when the power semiconductor element 23 is switched. Therefore, it is possible to suppress detection of light that becomes noise by means of the light detection unit 70 in a time period other than the timing at which the power semiconductor element 23 is switched. As a result, occurrence of erroneous detection can be avoided.

### Second Embodiment

Next, a second embodiment of the power conversion device 100 according to the present disclosure will be described. In the second embodiment described below, the same reference numerals will be assigned to configurations common to those of the above-described first embodiment in the drawings, and description thereof will be omitted. In the second embodiment, the arrangement of the light detection unit 70 in the power module 400 is different from the arrangement of the light detection unit 70 described in the first embodiment.

### Light Detection Unit

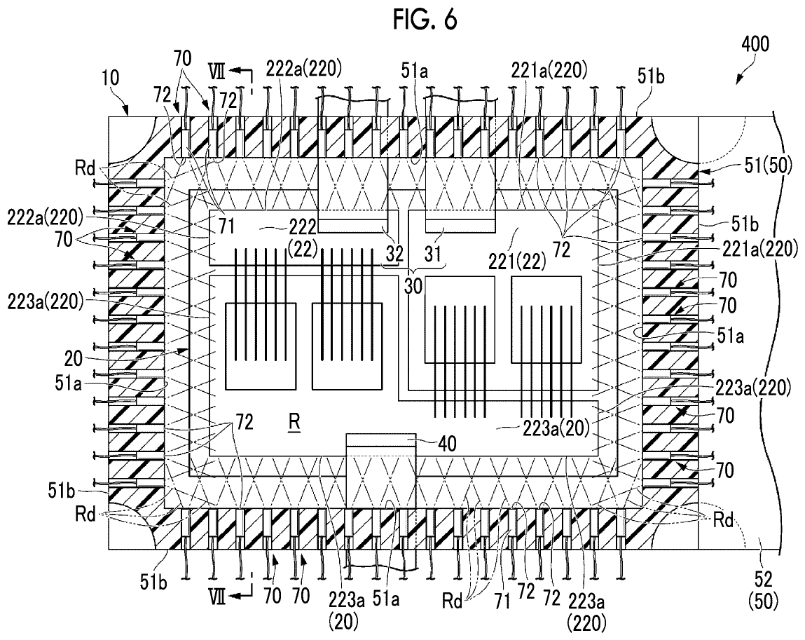

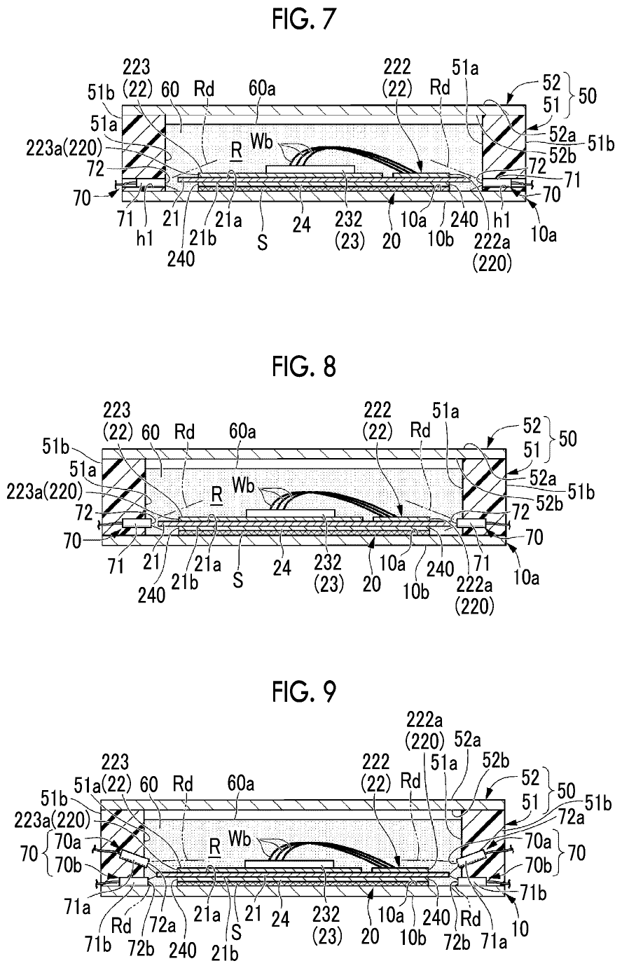

As illustrated in FIGS. 6 and 7, a plurality of light detection units 70 in the present embodiment are disposed on the side wall portion 51 of the case 50. The tip portion 71 of the light detection unit 70 is held in a state of being inserted into a hole h1 formed from the outer surface 51b to the inner surface 51a of the side wall portion 51. The tip surface 72 of the tip portion 71 in the present embodiment is flush with the inner surface 51a of the side wall portion 51. The tip surfaces 72 of the plurality of light detection units 70 are arranged side by side along the side edge portions 220 and 240 so that the light detection range Rd includes the side edge portion 220 of the front surface pattern 22 and the side edge portion 240 of the back surface pattern 24.

As illustrated in FIG. 7, the tip surface 72 faces the side edge portion 220 of the front surface pattern 22 and the side edge portion 240 of the back surface pattern 24 via the insulating portion 60 in a direction in which the inner surface 51a of the side wall portion 51 and the side edge portion 220 of the front surface pattern 22 face each other. As illustrated in FIG. 6, two adjacent light detection units 70 among the plurality of light detection units 70 arranged side by side along the side edge portions 220 and 240 are disposed such that at least parts of the respective light detection ranges Rd overlap each other when viewed from the direction in which the inner surface 51a and the side edge portions 220 and 240 face each other.

At this time, the tip surface 72 of the light detection unit 70 is disposed between the base plate 10 and the P-type terminal 31 connected to the first front surface pattern 221, the N-type terminal 32 connected to the second front surface pattern 222, and the output terminal portion 40 connected to the third front surface pattern 223.

### Operations and Effects

According to the above configuration, since the tip surface 72 of the light detection unit 70 faces the side edge portion 220 of the front surface pattern 22, light generated by partial discharge is easily incident on the light detection unit 70 from the tip surface 72 as compared with the configuration described in the first embodiment. That is, the detection sensitivity of the partial discharge by the light detection unit 70 is improved. As a result, partial discharge can be detected with higher accuracy.

In addition, since the tip surface 72 of the light detection unit 70 also faces the side edge portion 240 of the back surface pattern 24 and the side edge portion 240 is included in the light detection range Rd, when partial discharge occurs from the back surface pattern 24, the partial discharge can be detected. Therefore, it is possible to further suppress the detection failure of the partial discharge occurring in the circuit board 20.

The light detection unit 70 is disposed closer to the base plate 10 than the P-type terminal 31 and the N-type terminal 32 of the main terminal portion 30 and the output terminal portion 40. As a result, the P-type terminal 31, the N-type terminal 32, and the output terminal portion 40 do not become blind spots within the light detection range Rd from the light detection unit 70, as compared with a configuration in which the light detection unit 70 is disposed in the lid portion 52. Therefore, the occurrence of detection failure of partial discharge can be suppressed.

### Third Embodiment

Next, a third embodiment of the power conversion device 100 according to the present disclosure will be described. In the third embodiment to be described later, the same reference numerals are given to the configurations common to the configurations of the first and second embodiments in the drawings, and the description thereof will be omitted. In the third embodiment, the arrangement of the light detection unit 70 in the power module 400 is different from the arrangement of the light detection unit 70 described in the first and second embodiments.

### Light Detection Unit

As illustrated in FIG. 8, a plurality of light detection units 70 in the present embodiment are disposed on the side wall portion 51 of the case 50. The light detection unit 70 is disposed on the side wall portion 51 integrally with the side wall portion 51. The tip portion 71 of the light detection unit 70 protrudes from the inner surface 51a of the side wall portion 51 toward the circuit board 20. The tip surface 72 of the tip portion 71 in the present embodiment is integrally disposed with the insulating portion 60 in the housing space R. The tip surface 72 faces the side edge portion 220 via the insulating portion 60 in a direction in which the inner surface 51a of the side wall portion 51 and the side edge portion 220 of the front surface pattern 22 face each other.

### Operations and Effects

According to the above configuration, since the tip portion 71 of the light detection unit 70 protrudes from the inner surface 51a of the side wall portion 51 toward the circuit board 20, the tip surface 72 of the tip portion 71 is close to the side edge portion 220 of the front surface pattern 22 in a state of facing the side edge portion 220. Accordingly, compared to the configuration described in the second embodiment, the light generated by the partial discharge is easily incident on the light detection unit 70 from the tip surface 72. That is, the detection sensitivity of the partial discharge by the light detection unit 70 is further improved. As a result, partial discharge can be detected with higher accuracy.

### Other Embodiments

Hitherto, the embodiments of the present disclosure have been described in detail with reference to the drawings. However, specific configurations are not limited to the configurations of each embodiment, and additions, omissions, and substitutions of configurations and other modifications can be made within the scope not departing from the concept of the present disclosure.

The term “parallel” in the present embodiment refers to a substantially parallel state, and slight manufacturing errors or design tolerances are allowed. That is, in the above embodiment, a configuration in which the main surface 10a and the back surface 10b of the base plate 10 and the first surface 21a and the second surface 21b of the first insulating plate 21 are in a back-to-back relationship in a state of being parallel to each other has been described. However, the present invention is not limited to this configuration, and the main surface 10a and the back surface 10b of the base plate 10 and the first surface 21a and the second surface 21b of the first insulating plate 21 may be slightly inclined.

In addition, in the first embodiment, the configuration in which the tip surface 72 of the light detection unit 70 faces the main surface 10a of the base plate 10 in a state of being parallel to the main surface 10a has been described, but the present invention is not limited to this configuration. For example, the light detection unit 70 may be disposed on the lid portion 52 of the case 50 in a state where the tip surface 72 is inclined with respect to the main surface 10a. In addition, the light detection unit 70 may be disposed on the side wall portion 51 of the case 50 in a state where the tip surface 72 is inclined with respect to the main surface 10a.

As illustrated in FIG. 9, the light detection unit 70 may include a first light detection unit 70a and a second light detection unit 70b. In this case, the first light detection unit 70a is disposed on the side wall portion 51 in a state where a tip surface 72a of a tip portion 71a is inclined with respect to the main surface 10a of the base plate 10. The second light detection unit 70b is disposed on the side wall portion 51 in a state in which a tip surface 72b of a tip portion 71b faces the side edge portion 240 of the back surface pattern 24 in the circuit board 20. In this case, the tip surfaces 72a of a plurality of the first light detection units 70a are arranged side by side along the side edge portion 220 of the front surface pattern 22 such that the light detection range Rd extending from the tip surfaces 72a includes the side edge portion 220 of the front surface pattern 22. The tip surfaces 72b of a plurality of the second light detection units 70b are arranged side by side along the side edge portion 240 such that the light detection range Rd extending from the tip surface 72b includes the side edge portion 240 of the back surface pattern 24. The tip surface 72a of the first light detection unit 70a and the tip surface 72b of the second light detection unit 70b are integrally disposed with the insulating portion 60 in the housing space R.

The configurations of the power modules 400 described in the above embodiments are not limited to independent configurations. The power module 400 may be configured by appropriately combining the components described in the embodiments.

In the above embodiment, the configuration of the power conversion device 100, in which the power conversion unit 4 is a 6-in-1 module having three power modules 400, has been described, but the present invention is not limited thereto. For example, in the power conversion device 100, the power conversion unit 4 may be a 2-in-1 module having one power module 400.

In the above embodiment, the inverter is described as an example of the power conversion device 100. However, the power conversion device 100 is not limited to the inverter. The power conversion device 100 may be, for example, a device that performs power conversion by means of the power semiconductor element 23, such as a converter or a combination of an inverter and a converter. When the power conversion device 100 is a converter, an AC voltage may be input from an external input power supply (not illustrated) to an external output conductor, the power semiconductor element 23 on the circuit board 20 may convert the AC voltage into a DC voltage, and the DC voltage from the power semiconductor element 23 may be output to the outside of the power conversion device 100 through the main terminal portion 30 and the connection conductor 3b.

### Appendix

The power module described in each embodiment and the power conversion device including the power module are understood as follows, for example.
(1) A power module 400 according to a first aspect includes a base plate 10; a circuit board 20 that is disposed on a main surface 10a of the base plate 10; a main terminal portion 30 configured to input power to a circuit pattern of the circuit board 20; an output terminal portion 40 configured to output the power converted by a power semiconductor element 23 connected to the circuit pattern; a case 50 that includes a side wall portion 51 that surrounds the circuit board 20 from a direction in which the main surface 10a extends in a state in which the side wall portion 51 is disposed on the main surface 10a to define a housing space R for housing the circuit board 20, and a lid portion 52 that is disposed on the side wall portion 51 so as to close the housing space R to close an inside of the housing space R; an insulating portion 60 that is disposed in the housing space R so as to embed the circuit board 20 from a direction perpendicular to the main surface 10a; and a light detection unit 70 that is disposed in the case 50 and configured to detect light generated in the housing space R when light is incident from tip surfaces 72, 72a, and 72b of the light detection unit 70, in which a plurality of the tip surfaces 72, 72a, and 72b of the light detection unit 70 are arranged side by side along a side edge portion (side edge portions 220 and 240) of the circuit pattern that faces an inner surface 51a of the side wall portion 51 in the housing space R so that a light detection range Rd includes the side edge portion.

Accordingly, the light of the partial discharge generated from the side edge portion of the circuit pattern is incident on the light detection unit 70 from the tip surfaces 72, 72a, and 72b. That is, the light of the partial discharge from the side edge portion is detected by the light detection unit 70.
(2) The power module 400 according to a second aspect is the power module 400 according to the first aspect, in which a plurality of the light detection units 70 are disposed integrally with the side wall portion 51 of the case 50, and the tip surface 72 of each of the light detection units 70 faces the side edge portion via the insulating portion 60 in a direction in which the inner surface 51a of the side wall portion 51 and the side edge portion of the circuit pattern face each other.

Accordingly, since the tip surface 72 of the light detection unit 70 faces the side edge portion of the circuit pattern, the light generated by the partial discharge is easily incident on the light detection unit 70 from the tip surface 72. As a result, the detection sensitivity of the partial discharge by the light detection unit 70 is improved.
(3) The power module 400 according to a third aspect is the power module 400 according to the second aspect, in which the tip surface 72, 72a, and 72b of each of the light detection units 70 is integrally disposed with the insulating portion 60 in the housing space R.

Accordingly, since the tip surfaces 72, 72a, and 72b of the light detection unit 70 come close to the side edge portion of the circuit pattern in a state of facing the side edge portion, the detection sensitivity of the partial discharge by the light detection unit 70 is further improved.
(4) A power conversion device 100 according to a fourth aspect includes the power module 400 according to any one of the first aspect to third aspects; a gate drive device 6 configured to control switching of the power semiconductor element 23; a photoelectric conversion element 7 configured to convert light from the light detection unit 70 into a light reception signal voltage; a synchronization processing device 8 configured to synchronize a timing at which a voltage applied from the gate drive device 6 to the power semiconductor element 23 changes with a timing at which the photoelectric conversion element 7 converts the light into the light reception signal voltage and acquiring the light reception signal voltage from the photoelectric conversion element 7; and a detection device 9 configured to detect presence or absence of an abnormality in the circuit pattern within the light detection range Rd based on a magnitude of the light reception signal voltage acquired by the synchronization processing device 8.

Thus, the detection device 9 detects the presence or absence of partial discharge from the timing at which the power semiconductor element 23 starts switching. That is, it is possible to prevent the light detection unit 70 from detecting light that becomes noise in a time period other than the timing at which the power semiconductor element 23 is switched.

### INDUSTRIAL APPLICABILITY

According to the present disclosure, it is possible to provide a power module capable of accurately detecting partial discharge occurring from an end portion of a circuit pattern, and a power conversion device including the same.

### REFERENCE SIGNS LIST

1: Casing
1a: Input side surface
1b: Output side surface
2: External input conductor
3: Capacitor
3a: Capacitor body
3b: Connection conductor
3n: Negative electrode side terminal
3p: Positive electrode side terminal
4: Power conversion unit
5: Cooling device
6: Gate drive device
7: Photoelectric conversion element
8: Synchronization processing device
9: Detection device
10: Base plate
10a: Main surface
10b: Back surface
11: Cable
20: Circuit board
21: First insulating plate
21a: First surface
21b: Second surface
22: Front surface pattern
23: Power semiconductor element
24: Back surface pattern
30: Main terminal portion
31: P-type terminal
32: N-type terminal
40: Output terminal portion
50: Case
51: Side wall portion
51a: Inner surface
51b: Outer surface
52: Lid portion
52a: Surface
52b: Contact surface
60: Insulating portion
61: Second insulating plate
62: Gate drive pattern
70: Light detection unit
70a: First light detection unit
70b: Second light detection unit
71, 71a, 71b: Tip portion
72, 72a, 72b: Tip surface
91: Acquisition unit
92: Determination unit
93: Notification unit
94: Storage unit
100: Power conversion device
220, 240: Side edge portion
221: First front surface pattern
221a: First side edge portion
222a: Second side edge portion
223a: Third side edge portion
222: Second front surface pattern
223: Third front surface pattern
231: First power semiconductor element
232: Second power semiconductor element
400: Power module
D1: Opposite direction
h1: Hole
R: Housing space
Rd: Light detection range
S: Bonding material
Wb: Bonding wire

1. A power module comprising:
a base plate;
a circuit board that is disposed on a main surface of the base plate;
a main terminal portion configured to input power to a circuit pattern of the circuit board;
an output terminal portion configured to output the power converted by a power semiconductor element connected to the circuit pattern;
a case that includes a side wall portion that surrounds the circuit board from a direction in which the main surface extends in a state in which the side wall portion is disposed on the main surface to define a housing space for housing the circuit board, and a lid portion that is disposed on the side wall portion so as to close the housing space to close an inside of the housing space;
an insulating portion that is disposed in the housing space so as to embed the circuit board from a direction perpendicular to the main surface; and
a light detection unit that is disposed in the case and configured to detect light generated in the housing space when light is incident from a tip surface of the light detection unit,
wherein a plurality of the tip surfaces of the light detection unit are arranged side by side along a side edge portion of the circuit pattern that faces an inner surface of the side wall portion in the housing space so that a light detection range includes the side edge portion.

2. The power module according to claim 1,
wherein a plurality of the light detection units are disposed integrally with the side wall portion of the case, and
the tip surface of each of the light detection units faces the side edge portion via the insulating portion in a direction in which the inner surface of the side wall portion and the side edge portion of the circuit pattern face each other.

3. The power module according to claim 2,
wherein the tip surface of each of the light detection units is integrally disposed with the insulating portion in the housing space.

4. A power conversion device comprising:
the power module according to claim 1;
a gate drive device configured to control switching of the power semiconductor element;
a photoelectric conversion element configured to convert light from the light detection unit into a light reception signal voltage;
a synchronization processing device configured to synchronize a timing at which a voltage applied from the gate drive device to the power semiconductor element changes with a timing at which the photoelectric conversion element converts the light into the light reception signal voltage and acquiring the light reception signal voltage from the photoelectric conversion element; and
a detection device configured to detect presence or absence of an abnormality in the circuit pattern within the light detection range based on a magnitude of the light reception signal voltage acquired by the synchronization processing device.
